(19) United States
(12) Patent Application Publication
(10) Pub. No.: US 2021/0168966 A1
(43) Pub. Date: Jun. 3, 2021

(54) COMPOSITE SUBSTRATE

(71) Applicant: NIPPON SEIKI CO., LTD., Niigata (JP)

(72) Inventor: Yasunari IIDA, Niigata (JP)

(21) Appl. No.: 16/756,451

(22) PCT Filed: Oct. 25, 2018
(86) PCT No.: PCT/JP2018/039603

§ 371 Date: Apr. 15, 2020

(30) Foreign Application Priority Data
Oct. 30, 2017 (JP) 2017-209427

(51) Int. Cl. H05K 7/20; G02B 27/01; G03B 21/16; G03B 21/20

(52) U.S. Cl. CPC H05K 7/2039; G02B 27/0149; B60K 35/00; G03B 21/2033; G02B 2027/0161; G03B 21/16

(57) ABSTRACT

Provided is a composite substrate which is able to be reduced in influence by the difference of linear expansion coefficient among constituent materials. A composite substrate according to the present invention is provided with: a quadrangular heat dissipation plate which has a corner part, while having a light source on the surface; a quadrangular LED substrate which has a corner part, while having an opening in which the heat dissipation plate is arranged; and an adhesive which bonds the heat dissipation plate and the LED substrate with each other. The heat dissipation plate is arranged such that the corner part of the heat dissipation plate is rotated with respect to the corner part of the LED substrate. The corner part of the heat dissipation plate is rotated with respect to the corner part of the LED substrate by almost 45 degrees.

### TECHNICAL FIELD

The present invention relates to a composite substrate including a heat dissipation plate.

### BACKGROUND ART

High-output semiconductors such as high-brightness LEDs (Light Emitting Diodes) are used in devices requiring a high-brightness light source such as a head-up display mounted on a vehicle (for example, see Patent Document 1). In the case of high-brightness LEDs, since heat affects light output, dealing with the heat is an issue.

### PRIOR ART DOCUMENT

### Patent Document

Patent Document 1: Japanese Unexamined Patent Application Publication No. 2016-218259

### SUMMARY OF THE INVENTION

### Problems to be Solved by the Invention

For example, for heat dissipation from the LED, it is conceivable to provide, on a substrate, a heat dissipation plate made of a material having excellent thermal conductivity different from the material of the substrate on which the LED is mounted, and mount the LED on the heat dissipation plate. However, the adhesive that bonds the LED and the substrate, and the wiring that crosses over the LED and the substrate may be broken or disconnected at or near the interface due to a difference in the linear expansion coefficient (thermal expansion coefficient) between different materials.

The present invention has been made in view of such circumstances, and an object thereof is to provide a composite substrate capable of reducing the influence by the difference in linear expansion coefficient between materials.

### Solution to Problem

To solve the above-described problems, a composite substrate according to the present invention includes a quadrangular heat dissipation plate that has a corner part, the quadrangular heat dissipation plate including a surface on which an electronic component is provided, a substrate in a shape of a quadrangle that has a corner part, the substrate including an opening in which the heat dissipation plate is arranged, and an adhesive member bonding the heat dissipation plate and the substrate, in the composite substrate, the heat dissipation plate is arranged such that the corner part of the heat dissipation plate is rotated with respect to the corner part of the substrate.

### Effect of the Invention

In the composite substrate according to the present invention, it is possible to reduce the influence by the difference in the linear expansion coefficient between materials.

### BRIEF DESCRIPTION OF THE DRAWINGS

FIG. 1 is an explanatory diagram illustrating a configuration of an optical system of a head-up display using a composite substrate according to the present embodiment.

FIG. 2 is a configuration diagram of a projection display device.

FIG. 3 is an explanatory diagram illustrating a configuration of an optical system of the projection display device.

FIG. 4 is a configuration diagram of an LED substrate of the projection display device.

FIG. 5 is an enlarged view for explaining an attachment structure for attaching the LED substrate to a housing.

FIG. 6 is a cross-sectional view along a thickness direction of the LED substrate.

### MODE FOR CARRYING OUT THE INVENTION

An embodiment of a composite substrate according to the present invention will be described with reference to the accompanying drawings. In the present embodiment, explanation will be provided by using an example in which the composite substrate according to the present invention is used as an LED substrate of a head-up display mounted on an automobile.

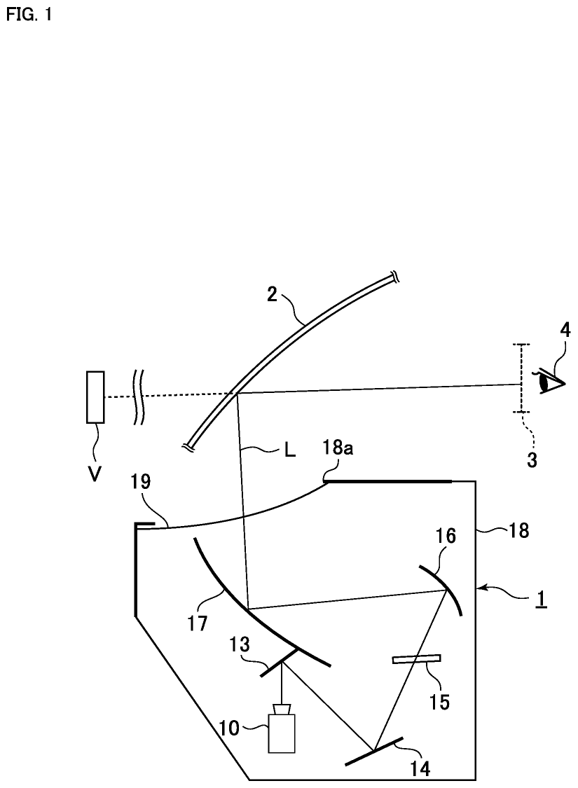

FIG. 1 is an explanatory diagram illustrating a configuration of an optical system of a head-up display using the composite substrate according to the present embodiment.

The head-up display 1 (hereinafter, referred to as HUD1) is arranged in an instrument panel of an automobile. The HUD 1 mainly includes a projection display device 10, a first plane mirror 13, a second plane mirror 14, a screen 15, a first concave mirror 16, a second concave mirror 17, and a case 18. The HUD 1 reflects display light L representing a display image displayed by the projection display device 10, on the first and the second plane mirrors 13 and 14 and the first and the second concave mirrors 16 and 17 forming a relay optical system, and emits the display light L toward a windshield 2 of an automobile, which is an example of a transmission-reflection unit. By placing a viewpoint 4 in an eye box 3 being an image visible region generated by the HUD 1, a viewer (mainly a driver) can visually recognize a virtual image V of the display image, which is superimposed on the scene (real scene) in front of the vehicle.

The projection display device 10 (display device 10) generates the display light L relating to the display image. The display device 10 will be described in detail below. The first plane mirror 13 reflects the display light L generated and emitted by the display device 10. The second plane mirror 14 further reflects the display light L reflected by the first plane mirror 13. The screen 15 receives the display light L reflected by the second plane mirror 14 and displays an image (real image). The first concave mirror 16 reflects the display light L emitted from the screen 15. The second concave mirror 17 reflects the display light L reflected by the first concave mirror 16 toward the windshield 2. The case 18 houses the display device 10, the first and the second plane mirrors 13 and 14, the screen 15, and the first and the second concave mirrors 16 and 17. The case 18 has an opening 18a at a portion facing the windshield 2. The opening 18a is covered by a light transmissive cover 19 that is light transmissive. The display light L reflected by the second concave mirror 17 passes through the light transmissive cover 19 and is emitted from the HUD 1.

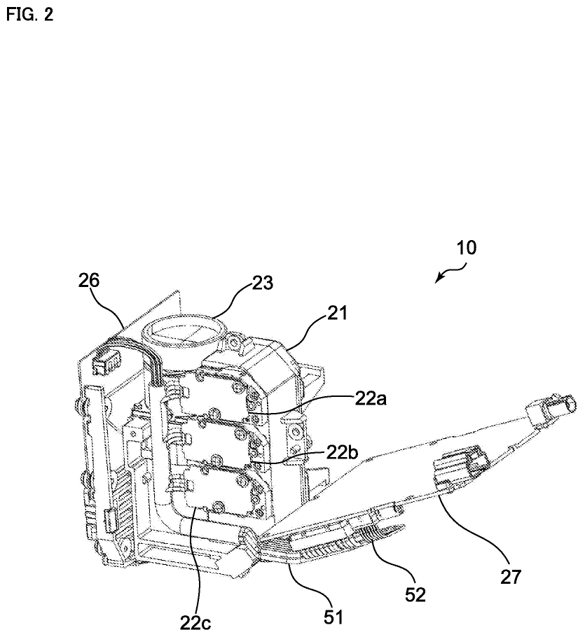

FIG. 2 is a configuration diagram of the display device 10.

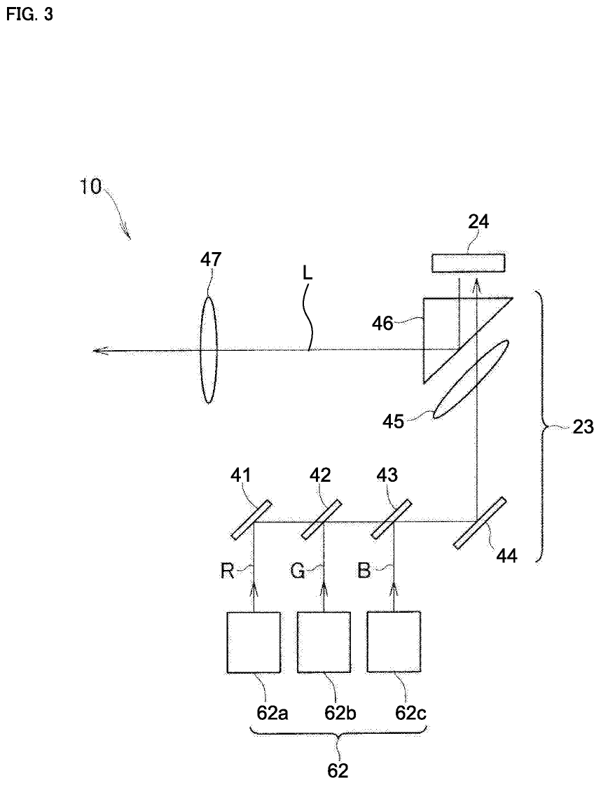

FIG. 3 is an explanatory diagram illustrating a configuration of the optical system of the display device 10.

The projection display device 10 includes a housing 21, an LED substrate 22, an optical member 23, a light modulation element 24, a light modulation element control substrate 26, and a main control substrate 27.

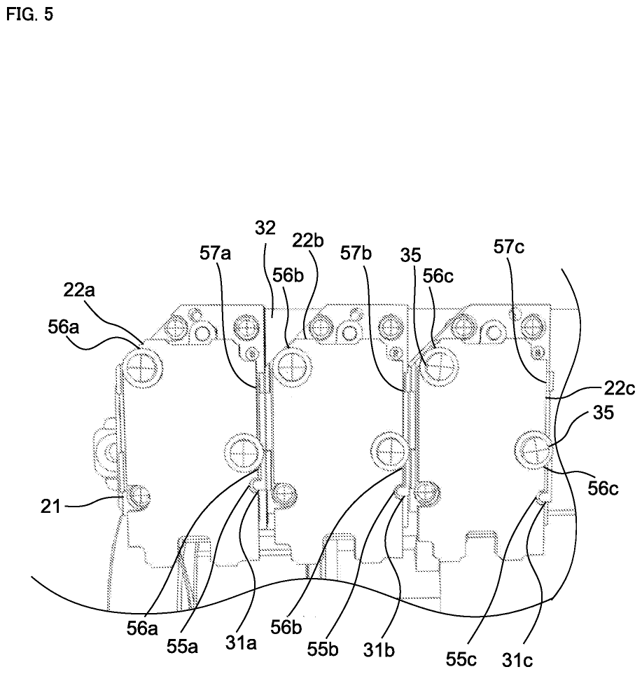

The housing 21 houses the optical member 23. The housing 21 has a structure for attaching the light modulation element 24 and each of the substrates 22, 26, and 27. In particular, the housing 21 includes a plurality of protruding units for preventing erroneous assembly 31a, 31b, and 31c (housing-side attachment units) (see FIG. 5) for attaching the LED substrate 22.

The LED (Light Emitting Diode) substrate 22 includes a first substrate 22a, a second substrate 22b, and a third substrate 22c, each of which includes a different light source mounted thereon. A red light source 62a that emits a red light beam R is mounted on the first substrate 22a. A green light source 62b that emits a green light beam G is mounted on the second substrate 22b. A blue light source 62c that emits a blue light beam B is mounted on the third substrate 22c. In the description below, in a context in which the first to third substrates 22a, 22b, and 22c are not distinguished, they are simply referred to as the LED substrate 22. In a context in which the red light source 62a, the green light source 62b, and the blue light source 62c are not distinguished, they are simply referred to as the light sources 62. The details of the LED substrate 22 will be described below.

As illustrated in FIG. 3, the optical member 23 includes a mirror 41, dichroic mirrors 42 and 43, a reflection mirror 44, a convex lens 45, a prism 46, and a light projecting lens 47.

The red light beam R emitted from the red light source 62a is reflected by the mirror 41 and passes through the dichroic mirrors 42 and 43. The green light beam G emitted from the green light source 62b is reflected by the dichroic mirror 42 and passes through the dichroic mirror 43. The blue light beam B emitted from the blue light source 62c is reflected by the dichroic mirror 43. The light beams R, G, and B are reflected by the reflection mirror 44, distributed by the convex lens 45, and transmitted through the prism 46. The transmitted light beams R, G, and B are converted to the display light L by the light modulation element 24. The display light L is reflected by the prism 46, transmitted through the light projecting lens 47, and projected (emitted).

The light modulation element 24 is, for example, a reflective display element such as a DMD (Digital Mirror Device) or an LCOS (Liquid Crystal On Silicon).

The light modulation element control substrate 26 is connected to the light modulation element 24 and controls the light modulation element 24.

The main control substrate 27 is connected to the LED substrate 22 via a wiring 51 and controls the LED substrate 22. Further, the main control substrate 27 is connected to the light modulation element control substrate 26 via a wiring 52 and controls the light modulation element control substrate 26.

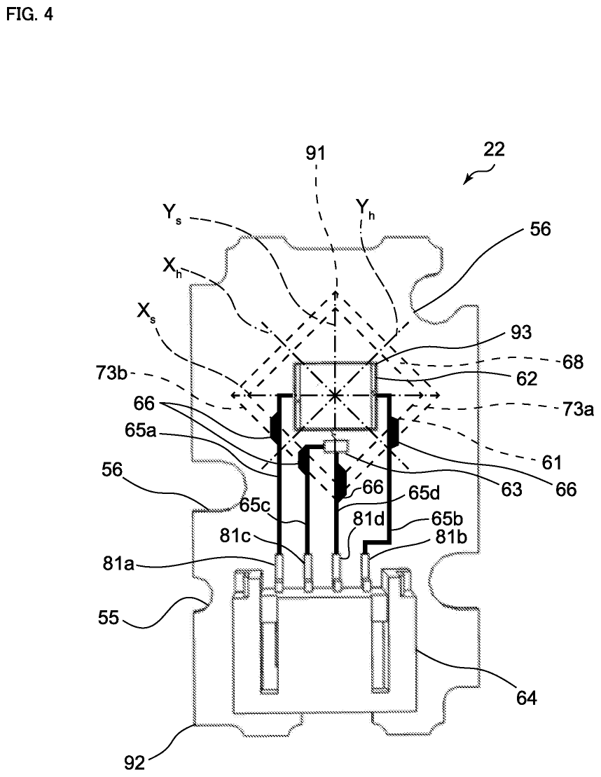

FIG. 4 is a configuration diagram of the LED substrate 22 of the display device 10.

The LED substrate 22 is a glass epoxy substrate in which FR4 (Flame Retardant Type 4) material is used as a base material, for example. Due to the manufacturing process, the LED substrate 22 has, as fiber directions, a lengthwise direction and a crosswise direction orthogonal to the lengthwise direction. The fiber directions are substantially coincident with the directions of the orthogonal sides (Xs-Ys) of the LED substrate 22. The LED substrate 22 is substantially rectangular (quadrangular) and includes a notch for preventing erroneous assembly 55 (55a, 55b, and 55c) (substrate-side attachment units), and a screwing notch 56 (56a, 56b, and 56c). The notches for preventing erroneous assembly 55 are used to position the housing 21, and form pairs with the protruding units for preventing erroneous assembly 31a, 31b, and 31c of the housing 21. Moreover, the screwing notch 56 (56a, 56b, 56c) is used at the time of screwing to the housing 21, and forms a pair with the screw hole (not illustrated) of the housing 21.

Here, FIG. 5 is an enlarged view for explaining an attachment structure for attaching the LED substrate 22 to the housing 21.

The LED substrate 22 is positioned to an attachment wall 32 of the housing 21 and then fixed with screws 35. The notches for preventing erroneous assembly 55a, 55b, and 55c of the first to the third substrates 22a, 22b, and 22c are provided at different positions on sides 57a, 57b, and 57c of the rectangles, respectively. Further, the protruding units for preventing erroneous assembly 31a, 31b, and 31c of the housing 21 are provided at different positions corresponding to the positions of the notches for preventing erroneous assembly 55a, 55b, and 55c. That is, the pair of protruding unit 31a and notch 55a, the pair of protruding unit 31b and notch 55b, and the pair of protruding unit 31c and notch 55c are provided at different positions. Thus, if an attempt is made to attach the LED substrate 22 at an incorrect position, the LED substrate will not fit. For this reason, upon attaching the LED substrate 22 to the housing 21, it is possible to prevent erroneous attachment of the LED substrate 22.

As illustrated in FIG. 4, the LED substrate 22 includes a heat dissipation plate 61, an adhesive 68, the light source 62, a thermistor 63, a connector 64, and wirings 65a to 65d.

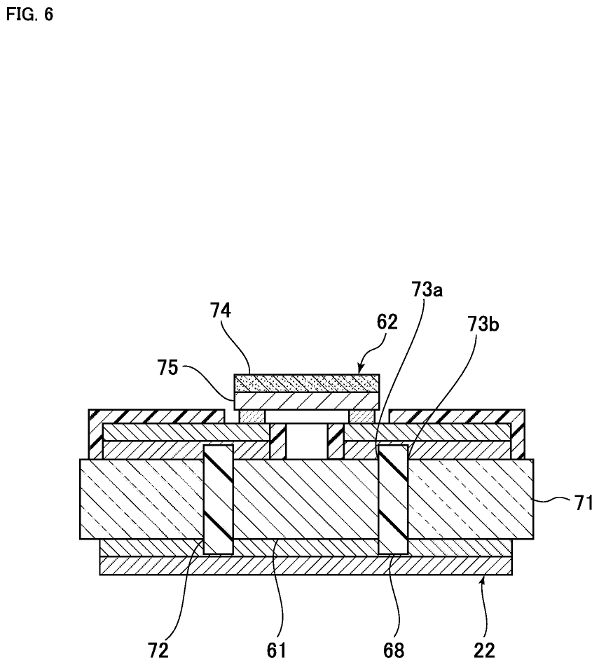

The heat dissipation plate 61 is substantially square (quadrangular) in a plan view. The heat dissipation plate 61 includes the light source 62 (electronic component) on the surface thereof, and dissipates the heat from the light source 62. The heat dissipation plate 61 is made of a material having good thermal conductivity and insulating properties, for example, aluminum nitride (AlN) (ceramics). From the viewpoint of thermal characteristics and the viewpoint of temperature detection by the thermistor 63, the heat dissipation plate 61 is preferably made of the same material as the material of a base 75 of the light source 62. Here, FIG. 6 is a cross-sectional view along the thickness direction of the LED substrate 22. The LED substrate 22 includes an opening 72 in which the heat dissipation plate 61 is arranged. The adhesive 68 (adhesive member) is, for example, an epoxy resin, and bonds the heat dissipation plate 61 and the LED substrate 22.

The light source 62 is a surface-mounted electronic component connected to the wirings 65a and 65b, and is substantially quadrangular in a plan view. Since the light source 62 emits heat during driving, the light source 62 is provided on the heat dissipation plate 61. The light source 62 includes an LED element 74 and the base 75. The base 75 is made of aluminum nitride, for example.

The thermistor 63 (electronic component) is an electronic component connected to the wirings 65c and 65d, and is provided on the heat dissipation plate 61 to detect the temperature. Information about the temperature of the heat dissipation plate 61 detected by the thermistor 63 is output to the main control substrate 27 as the temperature of the light source 62 and is used for controlling the light source 62 and the like.

The connector 64 includes terminals 81a to 81d. Moreover, the wirings 65a to 65d connect the light source 62 and the connector 64 (component on the substrate). The connector 64 supplies power to the light source 62 by connecting the LED substrate 22 and a power supply (not illustrated) at the terminal 81a via the wiring 65a. The connector 64 connects the light source 62 and the ground (not illustrated) at the terminal 81b via the wiring 65b. The connector 64 supplies power to the thermistor 63 by connecting the thermistor 63 and a power supply (not illustrated) at the terminal 81c via the wiring 65c. The connector 64 supplies a signal output from the thermistor 63 to the main control substrate 27 by connecting the thermistor 63 and the main control substrate 27 via the wiring 65d at the terminal 81d. Among the terminals 81a to 81d, the terminals 81a and 81b are arranged on an outer side. Among the terminals 81a to 81d, the terminals 81c and 81d are arranged on an inner side.

Each of the wirings 65a to 65d includes a reinforcement unit 66 in a part of the wiring extending from an interface 73a between the heat dissipation plate 61 and the adhesive 68 to an interface 73b between the LED substrate 22 and the adhesive 68, and the reinforcement unit 66 has a larger line width than the other parts of the wiring.

Next, the arrangement of components on the LED substrate 22 will be described.

As illustrated in FIG. 4, the light source 62 is arranged substantially at the center of the heat dissipation plate 61.

The heat dissipation plate 61 is arranged such that a corner part 91 of the heat dissipation plate 61 is rotated with respect to a corner part 92 of the LED substrate 22 by about 45 degrees. In other words, if the heat dissipation plate 61 and the LED substrate 22 are in a shape of a quadrangle having two orthogonal sides, the orthogonal axes Xh-Yh defining the directions of the two orthogonal sides of the heat dissipation plate 61 are rotated by about 45 degrees with respect to the orthogonal axes Xs-Ys defining the directions of the two orthogonal sides of the LED substrate 22.

Here, if the light source 62 emits heat, the heat is transmitted to the LED substrate 22 via the heat dissipation plate 61. As described above, the LED substrate 22 has fiber directions, and as is known, the density is different between the lengthwise direction and the crosswise direction, resulting in differences in various characteristics such as the linear expansion coefficient. Thus, the LED substrate 22 affected by the heat of the light source 62 has different expansion coefficients in the lengthwise and crosswise directions. Specifically, the expansion coefficient is smaller in the lengthwise direction than in the crosswise direction. Further, when the lengthwise direction and the crosswise direction are compared, a difference in the linear expansion coefficient with respect to the heat dissipation plate 61 is larger in the crosswise direction. Thus, the interface orthogonal to the crosswise direction is more largely expanded or contracted, and affected than the interface in the lengthwise direction, which may lead to breakage of the bonded site.

On the other hand, in the LED substrate 22 in the present embodiment, the heat dissipation plate 61 is inclined by about 45 degrees with respect to the fiber directions (Xs-Ys directions). As a result, as a whole, the interfaces 73a and 73b are not orthogonal to the crosswise direction, and the influence of the thermal expansion in the crosswise direction having the largest linear expansion coefficient can be reduced.

Further, in consideration of the influence of expansion and contraction at the interface, the part of the wiring extending from the interface 73a to the interface 73b is preferably designed to extend in a direction coinciding with the lengthwise direction. However, limiting the wiring direction to the lengthwise direction reduces the degree of freedom of the design. That is, if wiring is not formed in the direction coinciding with the crosswise direction, the direction in which the wiring can be led out from the heat dissipation plate 61 is limited.

In the LED substrate 22 in the present embodiment, the heat dissipation plate 61 is inclined by about 45 degrees with respect to the fiber directions (the orthogonal sides of the LED substrate 22). As a result, there is no difference in linear expansion due to the lengthwise and crosswise relationship, between the heat dissipation plate 61 and the LED substrate 22, in any of the sides of the heat dissipation plate 61, which results in a similar (uniform) expansion or contraction. Thus, there is no side on which the effect of large thermal expansion is exerted, and so it is possible to reduce the effect of large (maximum) expansion and contraction due to heat in any of the wirings 65a to 65d, and thus reduce the breakage (disconnection) of the wiring.

Further, the wirings 65a to 65d are provided with the reinforcement unit 66. Thus, even if the wirings 65a to 65d are affected by the expansion and contraction due to heat, it is possible to prevent the wirings 65a to 65d from disconnecting.

Although some embodiments of the present invention have been described, these embodiments are presented by way of example and are not intended to limit the scope of the invention. These novel embodiments can be implemented in various other forms, and various omissions, replacements, and changes can be made without departing from the scope of the invention. These embodiments and modifications thereof are included in the scope and gist of the invention, and are included in the invention described in the claims and the equivalents thereof.

For example, the amount of rotation of the corner part 91 of the heat dissipation plate 61 with respect to the corner part 92 of the LED substrate 22 and a corner part 93 of the light source 62 is not limited to 45 degrees. Further, the heat dissipation plate 61, the LED substrate 22, and the light source 62 are not limited to a quadrangular shape having two orthogonal sides, and may be diamond-shaped having two sides that are not orthogonal.

An example of the LED substrate 22 in which the expansion coefficient in the lengthwise direction is smaller than that in the crosswise direction has been described, but the lengthwise direction and crosswise direction may have the reverse relationship. Further, an example in which the fiber directions (lengthwise direction, crosswise direction) are substantially coincident with the directions of the orthogonal sides of the LED substrate 22 (Xs-Ys directions) has been described, but the present invention is not limited thereto. That is, since the orthogonal axes Xh-Yh of the heat dissipation plate is inclined with respect to the orthogonal axes Xs-Ys of the LED substrate 22, it is not necessary to take the fiber directions into consideration when the LED substrate 22 is taken from a worksheet.

The materials of heat dissipation plate 61 and the base 75 are not limited to aluminum nitride (AlN). For example, the material of the base 75 may be selected from aluminum (Al), gallium nitride (GaN), copper (Cu), and the like. If the heat dissipation plate 61 is made of a conductive material, an insulating layer and a copper foil pattern are laminated, and the light source (LED) is mounted thereon. The difference in the thermal expansion coefficient between the heat dissipation plate 61 and the base 75 is preferably less than 1 (10−6/K). Most preferably, the heat dissipation plate 61 are made of the same material as the base 75 to eliminate difference in thermal expansion coefficient.

### DESCRIPTION OF REFERENCE NUMERALS

1 Head-up display (HUD)
2 Windshield
3 Eye box
4 Viewpoint
10 Projection display device (display device)
13 First plane mirror
14 Second plane mirror
15 Screen
16 First concave mirror
17 Second concave mirror
18 Case
18a Opening
19 Light transmissive cover
21 Housing
22 LED substrate
22a First substrate
22b Second substrate
22c Third substrate
23 Optical member
24 Light modulation element
26 Light modulation element control substrate
27 Main control substrate
31a, 31b, 31c Protruding unit for preventing erroneous assembly
32 Attachment wall
41 Mirror
42, 43 Dichroic mirror
44 Reflection mirror
45 Convex lens
46 Prism
47 Light projecting lens
51, 52 Wiring
55, 55a, 55b, 55c Notch for preventing erroneous assembly
61 Heat dissipation plate
62 Light source
62a Red light source
62b Green light source
62c Blue light source
63 Thermistor
64 Connector
65a, 65b, 65c, 65d Wiring
66 Reinforcement unit
68 Adhesive
71, 75 Base
72 Opening
73a, 73b Interface
74 LED element
81a, 81b, 81c, 81d Terminal
91, 92, 93 Corner part

1. A composite substrate, comprising:
a quadrangular heat dissipation plate that has a corner part, the quadrangular heat dissipation plate including a surface on which an electronic component is provided;
a substrate in a shape of a quadrangle that has a corner part, the substrate including an opening in which the heat dissipation plate is arranged; and
an adhesive member bonding the heat dissipation plate and the substrate, wherein
the heat dissipation plate is arranged such that the corner part of the heat dissipation plate is rotated with respect to the corner part of the substrate.

2. The composite substrate according to claim 1, wherein
in the heat dissipation plate, the corner part of the heat dissipation plate is rotated with respect to the corner part of the substrate by an angle substantially equal to 45 degrees.

3. The composite substrate according to claim 1 or 2, further comprising a wiring connecting the electronic component and a component on the substrate, wherein
the wiring includes a reinforcement unit at least in a part of the wiring extending from an interface between the heat dissipation plate and the adhesive member to an interface between the substrate and the adhesive member, the reinforcement unit having a larger line width than the other parts of the wiring.

4. The composite substrate according to claim 1, wherein
the substrate has fiber directions that are substantially coincident with directions of orthogonal sides of the quadrangle.
